(19) United States
(12) Patent Application Publication
(10) Pub. No.: US 2006/0105495 A1
(43) Pub. Date: May 18, 2006

(54) Device and method for reshaping the interconnection elements of an electronic module using the stress reflow method and, in particular, for restoring the flatness thereof

(76) Inventor: Serge Dutheil, La Ciotat (FR)

Correspondence Address: WESTMAN CHAMPLIN & KELLY, P.A., SUITE 1400 - INTERNATIONAL CENTRE, 900 SECOND AVENUE SOUTH, MINNEAPOLIS, MN, 55402-3319, US

(21) Appl. No.: 10/529,811

(22) PCT Filed: Oct. 3, 2003
(86) PCT No.: PCT/FR03/02921

§ 371 Date: Sep. 27, 2005

(30) Foreign Application Priority Data
Oct. 4, 2002 (FR) 0212384

(51) Int. Cl. H01L 21/44

(52) U.S. Cl. 438/106

(57) ABSTRACT

A method and device are provided to reshape a set of conducting elements which are distributed over the inner face of an electronic module, said set of conducting elements forming means of positioning the module on a motherboard and/or electromagnetic armour means for the inner face of the module and/or means providing an electrical interconnection with the motherboard. The method comprises a reflow step whereby the module is subjected to the stress reflow method in a volume comprising walls having pre-determined shapes in order to enable destressing between at least some of the constituent elements of the module, such that the tips of the free ends of the set of conducting elements conform to the shape of a pre-determined two-dimensional or three-dimensional case. In one particular embodiment, the volume comprising the walls having pre-determined shapes is a volume in which a first wall, which is intended to be in contact with the tips of the free ends of the set of conducting elements, is a plane wall. In this case, the pre-determined two-dimensional or three-dimensional case is a plane and the reshaping consists in restoring the flatness thereof.

The field of the invention is that of electronics and radiocommunications.

More specifically, the invention relates to the repair of electronic modules (hereinafter referred to as “modules”) wherein the free ends of the conductive interconnection elements show a defect, in that the tops of said free ends do not fit a predetermined two-dimensional or three-dimensional envelope.

The invention applies particularly, but not exclusively, to the restoring of the flatness of the conductive elements (i.e. in the specific case where the two-dimensional or three-dimensional envelope is a plane). This is currently the most frequent case, wherein the surface of the motherboard on which the module is to be transferred is plane.

As an illustration, the technical problem and solutions according to the prior art, with their limitations, are discussed below, in the case of restoring of the flatness of the conductive elements. It is clear that this discussion may easily be transposed by those skilled in the art to reshaping the tops of conductive elements, with respect to any predetermined (and not necessarily plane) two-dimensional or three-dimensional envelope shape. Such a two-dimensional or three-dimensional envelope shape may for example result from the fact that the surface of the motherboard on which the module is to be transferred is not plane.

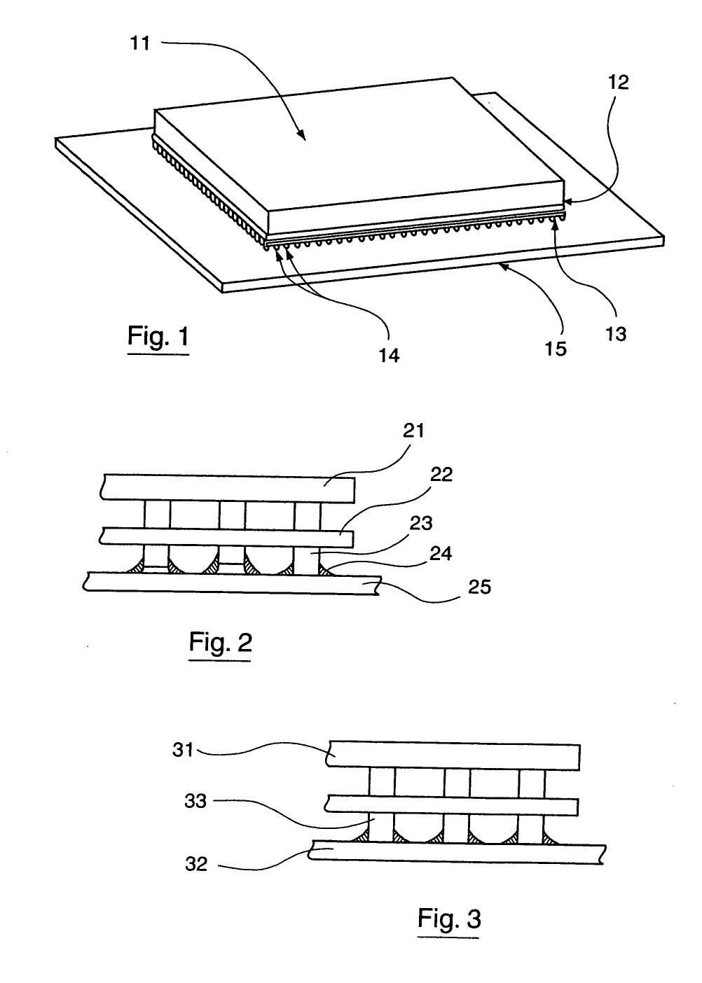

The invention is of particular interest in the case of a radiocommunication module, involving an interposition structure. Such a module, as shown in FIG. 1, generally consists physically of several elements:

a printed circuit board 12;

a cover 11 providing electromagnetic shielding and covering the electronic components supported on the top surface of the printed circuit board 12;

a set of other electronic components supported on the bottom surface of the printed circuit board;

an interconnection system (also referred to hereinafter as an “interposition structure”) 13 consisting of conductive elements 14 simultaneously forming electromagnetic shielding means of the bottom surface of the printed circuit board and/or electrical interconnection means and/or means to transfer onto a motherboard 15.

The mechanical stack produced in this way may, during the industrial manufacture of the modules, induce an unacceptable flatness defect, i.e. outside the tolerances usually recognised for any electronic component or macro-component on the conductive elements of these modules. In other words, due to the flatness defect, some modules cannot be transferred onto a motherboard.

A maximum flatness defect value generally permitted for a standard motherboard transfer operation is of the order of 100 to 150 microns.

As a general rule, whether the module comprises an interposition structure or not, the surface flatness defect that it is intended to correct may be the result of one or more causes (mechanical stack, set of original conductive elements of unequal length, release of stress on the module during one or more reflow cycles, etc.).

FIG. 2 illustrates a module 21 comprising an interposition structure 22 and showing empty interstices 23, characteristic of the surface flatness defect, between some of the free ends of the conductive elements 24 and the motherboard 25 whereon this module is transferred (by cream soldering or soldering paste 26). Due to these interstices, the good solderability criteria usually taken into account cannot be met when transferring the module onto the motherboard.

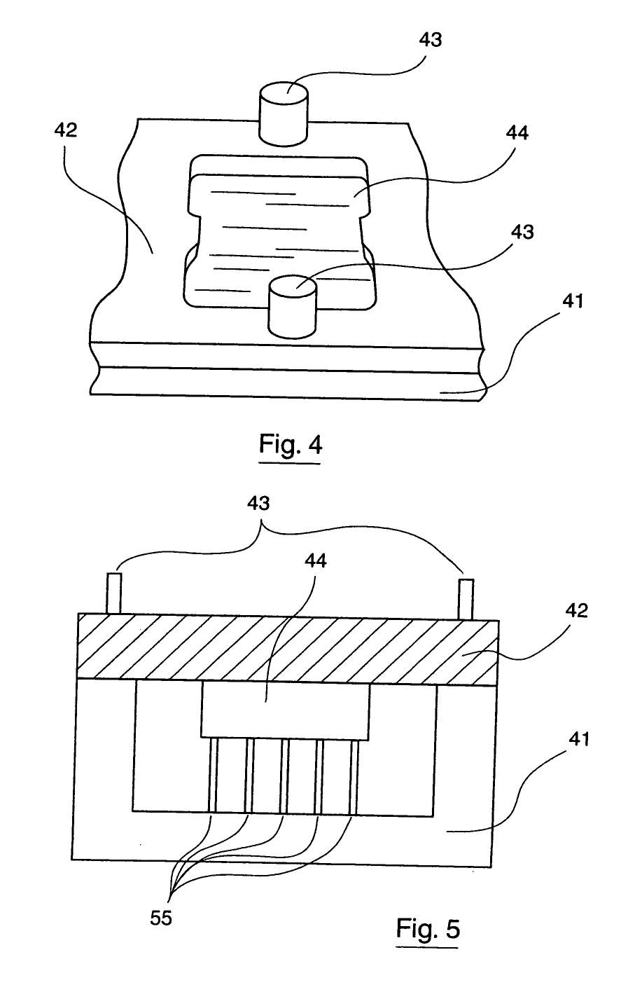

On the other hand, FIG. 3 illustrates the transfer of a module 31 onto a motherboard 32 showing no surface flatness defect, the tops of all the free ends of the conductive elements 33 being located roughly in the same plane. Therefore, there are few or no empty interstices between some of the free ends of the conductive elements and the motherboard. Therefore, the good solderability criteria usually taken into account can be met when transferring the module onto the motherboard.

In the prior art, there is no known method to date making it possible to repair a surface flatness defect (or more generally a defect with respect to a predetermined two-dimensional or three-dimensional shape) of the tops of the free ends of conductive elements for such modules. In fact, the majority of electronic component manufacturers consider, for economic reasons, that it is much less costly to select the defective electronic modules when they leave the production line and to dispose of them, rather than to repair them systematically or conditionally with a non-negligible increase in the unit cost of said modules as a result.

One drawback of this techno-economic approach of the prior art, consisting of scrapping defective electronic modules, is its non-negligible additional cost when scrapping more expensive modules. The term more expensive modules refers particularly, but not exclusively, to radiocommunication modules, with a much higher unit cost due to the complexity associated with their use and the technology contained.

The invention particularly aims to resolve this main drawback of the prior art.

More specifically, one of the aims of the invention is to provide a device and method for reshaping, particularly restoring the surface flatness, a set of conductive elements distributed on the bottom surface of an electronic module.

Another aim of the invention is to provide such a device and method, which are low in cost and easy to use.

A further aim of the invention is to contribute to reducing significantly the additional costs initially generated by the scrapping of modules.

These aims, along with others which will emerge hereinafter, are achieved using a method for reshaping a set of conductive elements distributed on the bottom surface of an electronic module, said set of conductive elements forming means to transfer the module onto a motherboard and/or electromagnetic shielding means for the bottom surface of the module and/or electrical interconnection means with the motherboard. The method comprises a module stress reflow step, in a volume with walls of predetermined shapes, to enable stress release between at least some of the constituent elements of the module, such that the tops of the free ends of the set of conductive elements fit a predetermined two-dimensional or three-dimensional envelope.

It is important to point out that the term stress reflow refers, firstly, to the application of thermal stress to the module (reflow method used) and, secondly, the application of mechanical stress by trapping the module in a volume with walls of predetermined shapes.

In addition, the term stress release between at least some of the constituent elements of the module refers to the release of at least some assembly connections between at least some of the constituent elements of the module.

In this way, the invention is based on a completely novel and inventive approach to the processing of modules showing a shape defect (particularly a surface flatness defect), meeting both economic cost and additional cost criteria and purely technical criteria. In fact, in the field of electronics and radiocommunications, those skilled in the art have always favoured, in the prior art, the scrapping of modules identified as defective, considering the additional cost induced on leaving the production line as negligible, given that said line generally produces hundreds of thousands, or even millions, of electronic modules or components at extremely low unit costs.

In a preferential embodiment of the invention, the volume with walls of predetermined shapes is a volume wherein the first wall, intended to be in contact with the tops of the free ends of the set of conductive elements, is a plane wall, the predetermined two-dimensional or three-dimensional envelope being a plane, said reshaping being reconditioning of the surface flatness.

Preferentially, the volume with walls of predetermined shapes is a volume wherein a second wall, intended to be in contact with the surface of the module opposite that whereon the conductive elements are distributed, is a plane wall.

Advantageously, the module stress reflow step comprises the following steps:

positioning of the module on a plate;

positioning of a back-plate on the plate, so as to trap and apply stress to the module in the volume with walls of predetermined shapes formed between the plate and the back-plate;

placing of the plate/module/back-plate superposition in a furnace, and heating according to a suitable temperature profile to enable stress release between at least some of the constituent elements of the module.

Advantageously, the heating step is followed by the following steps:

cooling of the plate/module-back-plate superposition;

release of the module from the volume with walls of predetermined shapes.

Also advantageously, the temperature profile is defined so as to exceed the vitreous transition point of the substrate to modify its mechanical constants and enable it to be deformed. In fact, the electronic module comprises at least one substrate that may be of the organic substrate type.

In a particular embodiment of the invention, the temperature profile is preferentially defined so as to release the mechanical stress on the solder seams between said connectors and at least one organic substrate, when at least one module substrate is of the connectorised type. In fact, in this embodiment, the electronic module comprises at least one substrate and at least one connector attached by at least one solder seam.

One of the principles of the invention consists of positioning the electronic component or module in a device enabling it to undergo a thermal process and a mechanical process. In this way, the electronic module is subjected jointly to mechanical stress and a thermal process.

In addition, the temperature profile is broken down into two parts, a first corresponding to a heating phase of the entire electronic module conducted in a furnace, and a second cooling part during which the electronic module and its constituent elements are subjected to mechanical stress up to a predetermined critical temperature.

Advantageously, during the module positioning step on the plate, the module is positioned in a suitable housing formed in the plate.

Advantageously, the back-plate positioning step on the plate comprises a back-plate tightening step against the plate, so as to optimise the application of stress to the module in the volume with walls of predetermined shapes formed between the plate and the back-plate.

The invention is applied advantageously to a radiocommunication module.

In an advantageous application of the invention, the module comprises conductive elements belonging the group comprising: columns, beads, inserts and loops.

The invention is also applied advantageously to a module comprising:

a printed circuit board whereon components are mounted;

an interposition structure, wherein:
a first surface supports a first set of conductive elements, so as to enable the transfer of said interposition structure, via its first surface, onto the bottom surface of said printed circuit board;
a second surface supports a second set of conductive elements, so as to enable the transfer of the module onto the motherboard, by transferring said interposition structure, via its second surface, onto the motherboard.

In this case, the method enables the reshaping of the second set of conductive elements.

In a first embodiment, the first and second sets of conductive elements are combined, the elements supported by the first surface of the interposition structure being pass-through and projecting onto the second surface of the interposition structure. In this case, said method is used to reshape the free ends of the conductive elements projecting onto the second surface of the interposition structure.

In a second embodiment, the first and second sets of conductive elements are not combined, each of the elements of the first set being connected to a first end of a conductive pass-through opening, a second end of each pass-through opening being connected to an element of the second set. In this case, said method is used to reshape the free ends of the conductive elements of the second set.

The invention also relates to a device for reshaping a set of conductive elements distributed on the bottom surface of an electronic module, said set of conductive elements forming means to transfer the module onto a motherboard and/or electromagnetic shielding means for the bottom surface of the module and/or electrical interconnection means with the motherboard. The device according to the invention comprises module stress reflow means, in a volume with walls of predetermined shapes, to enable stress release between at least some of the constituent elements of the module, such that the tops of the free ends of the set of conductive elements fit a predetermined two-dimensional or three-dimensional envelope.

Advantageously, the volume with walls of predetermined shapes is a volume wherein the first wall, intended to be in contact with the tops of the free ends of the set of conductive elements, is a plane wall, the predetermined two-dimensional or three-dimensional envelope being a plane, said reshaping being reconditioning of the surface flatness.

Advantageously, the volume with walls of predetermined shapes is a volume wherein a second wall, intended to be in contact with the surface of the module opposite that whereon the conductive elements are distributed, is a plane wall.

In a preferential embodiment, the module stress reflow means comprise:

a plate whereon the module is positioned;

a back-plate, intended to be positioned on the plate, so as to trap and apply stress to the module in the volume with walls of predetermined shapes formed between the plate and the back-plate;

a furnace in which the plate/module/back-plate superposition is placed, and used to heat the superposition according to a suitable temperature profile to enable stress release between at least some of the constituent elements of the module.

Advantageously, the module stress reflow means also comprise:

plate/module-back-plate superposition cooling means;

means to release the module from the volume with walls of predetermined shapes.

Also advantageously, the device according to the invention also comprises temperature profile application means making it possible to exceed the vitreous transition point of the substrate to modify its mechanical constants and enable it to be deformed.

In a particular embodiment of the invention using a substrate of the connectorised type, the device according to the invention comprises temperature profile application means making it possible to release the mechanical stress on the solder seams between said connectors and at least one organic substrate.

Advantageously, the plate comprises a housing wherein the shape is suitable to receive the module.

Preferentially, the back-plate positioning means on the plate comprise means to tighten the back-plate against the plate, making it possible to optimise the application of stress to the module in the volume with walls of predetermined shapes formed between the plate and the back-plate.

The invention also relates to a production method for electronic modules of the type each comprising a set of conductive elements distributed on the bottom surface of the module, said set of conductive elements forming means to transfer the module onto a motherboard and/or electromagnetic shielding means for the bottom surface of the module and/or electrical interconnection means with the motherboard. The production method comprises a step implementing the abovementioned method for reshaping a set of conductive elements distributed on the bottom surface of an electronic module.

In a first embodiment, the reshaping method implementation step is performed systematically, for all the modules manufactured.

In a second embodiment, the production method comprises a detection step of manufactured modules, referred to as defective modules, showing a shape defect, greater than a predetermined threshold, of the tops of the free ends of the conductive elements with respect to a predetermined two-dimensional or three-dimensional envelope. In addition, the reshaping method implementation step is only performed for said defective modules.

Other characteristics and advantages of the invention will emerge more clearly on reading the following description of a preferential embodiment, given simply as an illustrative and non-limitative example, and the appended figures, wherein:

FIG. 1, already described with respect to the prior art, represents a radiocommunication module comprising an interposition structure;

FIG. 2, also already described with respect to the prior art, illustrates a surface flatness defect of the interconnection elements of a module transferred onto a motherboard;

FIG. 3, also described with respect to the prior art and with FIG. 2, illustrates the optimal transfer of a module, wherein the interconnection elements do not show any surface flatness defect, onto a motherboard;

FIG. 4 illustrates a particular embodiment of the device, in three dimensions, according to the invention, for reconditioning the surface flatness of the interconnection elements of a module;

FIG. 5 represents a sectional view of the device in FIG. 4;

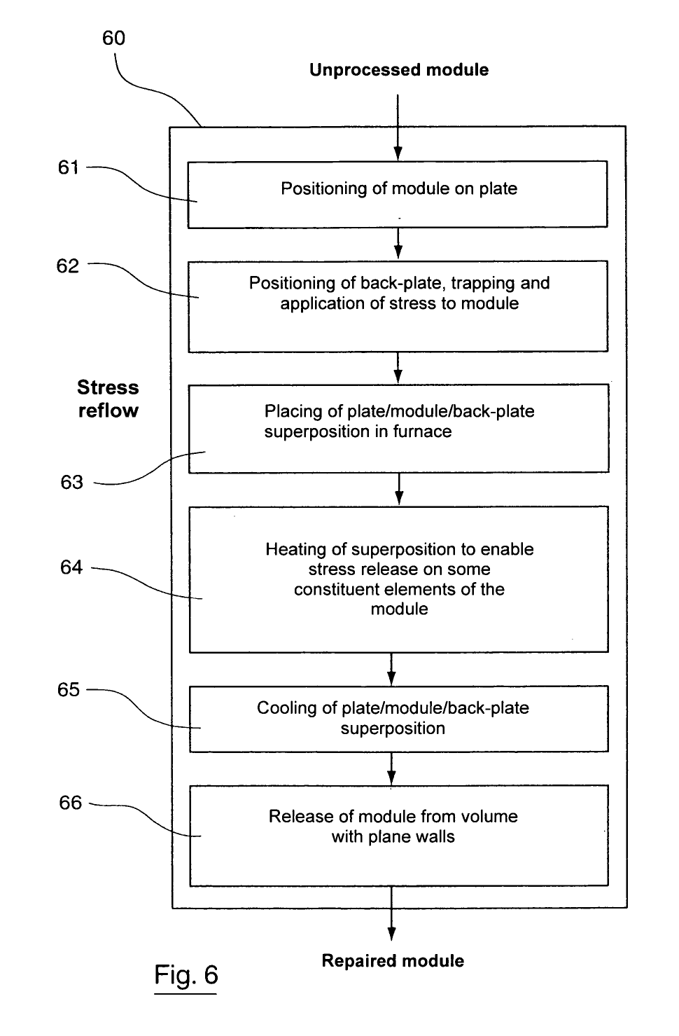

FIG. 6 represents a particular embodiment of the method, according to the invention, for reconditioning the surface flatness of the free ends of the conductive elements, by means of stress reflow;

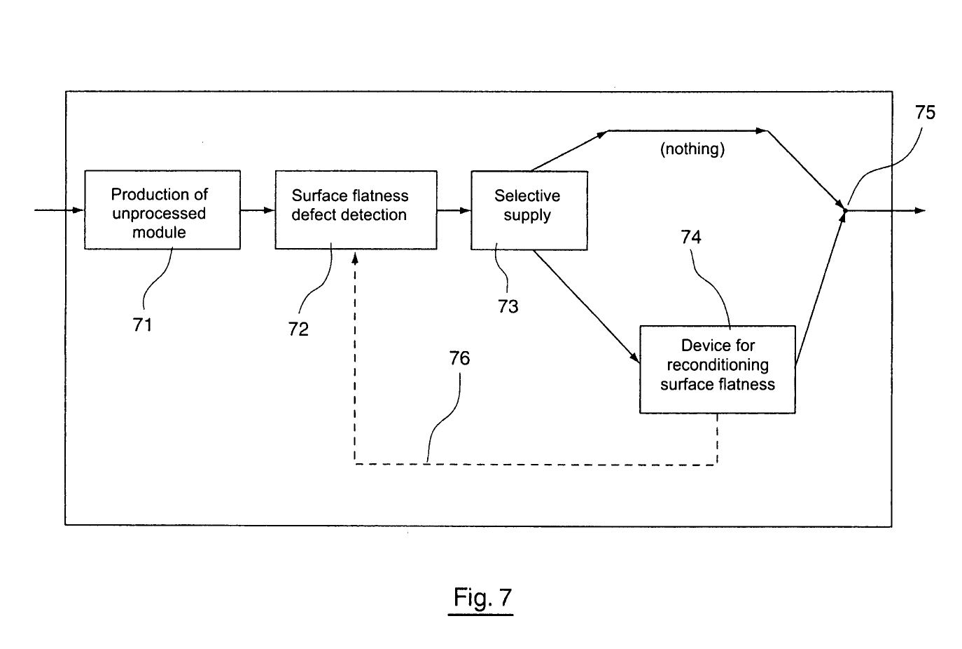

FIG. 7 illustrates the various steps of a particular embodiment of a module production method, including the method according to the invention for reconditioning the surface flatness of the conductive interconnection elements of the manufactured modules.

The general principle of the invention is based on stress reflow of the module, in a volume with walls of predetermined shapes (e.g. plane walls). In this way, the tops of conductive elements are reshaped, with a view to optimal subsequent transfer of the module onto a motherboard by means of soldering.

Hereinafter in the description, only the case wherein the reshaping consists of restoring the surface flatness of the tops of the free ends of the conductive elements is considered. However, it is clear that the present invention applies more generally to the reshaping of conductive elements such that the tops of their free ends fit a predetermined two-dimensional or three-dimensional envelope. This shape may be a function (e.g. complementary) of the shape of the surface of the motherboard receiving the module. For example, this shape comprises one or more shoulders.

A preferential embodiment of the method according to the invention for restoring the surface flatness of the interconnection elements of a module will now be presented. For example, these elements belong to the group comprising: columns, loops, inserts and beads. However, it is clear that this list is not exhaustive.

In the particular embodiment described in FIGS. 4 and 5, the device according to the invention, of the module to be repaired 44, comprises:

a plate 41, wherein the module is locked, the free ends of the conductive elements 43 thus turning downwards;

a back-plate 42 positioned on said plate 41;

at least two nuts 43 for tightening and applying stress to the module which is supported on its conductive interconnection elements 55.

The method according to the invention for restoring the surface flatness by means of stress reflow is based on the device described above (FIGS. 4 and 5) which is used to trap and apply stress to the module to be repaired in a volume with plane walls formed between the plate and the back-plate. It is also based on the following stress reflow steps 60, illustrated by the flow chart in FIG. 6:

positioning of the module in a suitable housing in a plate 61;

positioning of a back-plate on the plate 62;

transfer of the plate/module-back-plate superposition into a furnace 63;

heating 64 according to a suitable temperature profile to enable stress release, between at least some of the constituent elements of the module under repair;

cooling 65 of the plate/module/back-plate superposition;

release 66 of the repaired module from the volume with plane walls.

In a particular embodiment, the trapping of the module to be repaired may be followed by a tightening step, for example by means of nuts (FIGS. 4 and 5), so as to optimise the application of stress to the module in the volume with plane walls formed between the plate and the back-plate. The level of tightening may be controlled and/or programmed according to the mechanical resistance stress of the constituent elements of the modules to be repaired.

FIG. 7 represents a particular production method 70 of electronic or radiocommunication modules comprising several steps:

an unprocessed module production step 71;

a detection step of the surface flatness fault of some modules 72;

a selective supply step of the modules showing a surface flatness defect 73;

an implementation step of the method according to the invention (FIG. 6) for restoring the surface flatness of the conductive elements distributed on the bottom surface of the defective modules 74;

a pooling step 75 of the repaired modules and non-defective modules into the same set of modules that can all be transferred optimally onto a motherboard.

An advantageous alternative embodiment of this particular production method may consist of implementing, systematically, in the production line, said method according to the invention for restoring the surface flatness. In this way, all the modules leaving the production step are repaired.

According to another alternative embodiment of this particular production method, after the module repair step 74, the method loops to the surface flatness defect detection step 72 (as represented by the dotted arrows referenced 76 in FIG. 7). In this way, it is verified that the surface flatness of the repaired modules is correct.

In the particular embodiment described above, the module comprises an interposition structure containing the set of conductive interconnection elements. However, it is clear that the device and the method according to the invention for reconditioning the surface flatness may also be applied to any other module not using such an interposition structure, but wherein the interconnection elements may however show a surface flatness defect.

1. Method for reshaping a set of conductive elements distributed on the bottom surface of an electronic module, said set of conductive elements forming means to transfer the module onto a motherboard and/or electromagnetic shielding means for the bottom surface of the module and/or electrical interconnection means with the motherboard,
wherein said method comprises a module stress reflow step, in a volume with walls of predetermined shapes, to enable stress release between at least some of the constituent elements of the module, such that the tops of the free ends of the set of conductive elements fit a predetermined two-dimensional or three-dimensional envelope.

2. Method according to claim 1, wherein the volume with walls of predetermined shapes is a volume wherein the first wall, intended to be in contact with the tops of the free ends of the set of conductive elements, is a plane wall,
the predetermined two-dimensional or three-dimensional envelope being a plane, said reshaping being restoring of the surface flatness.

3. Method according to claim 2, wherein the volume with walls of predetermined shapes is a volume wherein a second wall, intended to be in contact with the surface of the module opposite that whereon the conductive elements are distributed, is a plane wall.

4. Method according to claim 1, wherein the module stress reflow step comprises the following steps:
positioning of the module on a plate;
positioning of a back-plate on the plate, so as to trap and apply stress to the module in the volume with walls of predetermined shapes formed between the plate and the back-plate;
placing of the plate/module/back-plate superposition in a furnace, and heating according to a suitable temperature profile to enable stress release between at least some of the constituent elements of the module.

5. Method according to claim 4, wherein the heating step is followed by the following steps:
cooling of the plate/module-back-plate superposition;
release of the module from the volume with walls of predetermined shapes.

6. Method according to claim 4, said electronic module comprising at least one substrate, wherein said temperature profile is defined so as to exceed the vitreous transition point of the substrate to modify its mechanical constants and enable it to be deformed.

7. Method according to claim 4, said electronic module comprising at least one substrate and at least one connector attached by at least one solder seam, wherein said temperature profile is defined so as to release the mechanical stress on the solder seams between said connectors and at least one organic substrate, when said substrate is of the connectorised type.

8. Method according to claim 3, wherein, during the module positioning step on the plate, the module is positioned in a suitable housing formed in the plate.

9. Method according to claim 3, wherein the back-plate positioning step on the plate comprises a back-plate tightening step against the plate, so as to optimise the application of stress to the module in the volume with walls of predetermined shapes formed between the plate and the back-plate.

10. Application of the method according to claim 1 to a radiocommunication module.

11. Application of the method according to claim 1, to a module comprising conductive elements belonging the group comprising: columns, beads, inserts and loops.

12. Application of the method according to claim 1 to a module comprising:
a printed circuit board whereon components are mounted;
an interposition structure, wherein:
a first surface supports a first set of conductive elements, so as to enable the transfer of said interposition structure, via its first surface, onto the bottom surface of said printed circuit board;
a second surface supports a second set of conductive elements, so as to enable the transfer of the module onto the motherboard, by transferring said interposition structure, via its second surface, onto the motherboard;
wherein said method enables the reshaping of the second set of conductive elements.

13. Application according to claim 12, wherein the first and second sets of conductive elements are combined, the elements supported by the first surface of the interposition structure being pass-through and projecting onto the second surface of the interposition structure,
and in that said method is used to reshape the free ends of the conductive elements projecting onto the second surface of the interposition structure.

14. Application according to claim 12, wherein the first and second sets of conductive elements are not combined, each of the elements of the first set being connected to a first end of a conductive pass-through opening, a second end of each pass-through opening being connected to an element of the second set,
and in that said method is used to reshape the free ends of the conductive elements of the second set.

15. Device for reshaping a set of conductive elements distributed on the bottom surface of an electronic module, said set of conductive elements forming means to transfer the module onto a motherboard and/or electromagnetic shielding means for the bottom surface of the module and/or electrical interconnection means with the motherboard,
wherein said device comprises module stress reflow means, in a volume with walls of predetermined shapes, to enable stress release between at least some of the constituent elements of the module, such that the tops of the free ends of the set of conductive elements fit a predetermined two-dimensional or three-dimensional envelope.

16. Device according to claim 15, wherein the volume with walls of predetermined shapes is a volume wherein the first wall, intended to be in contact with the tops of the free ends of the set of conductive elements, is a plane wall,
the predetermined two-dimensional or three-dimensional envelope being a plane, said reshaping being restoring of the surface flatness.

17. Device according to claim 16, wherein the volume with walls of predetermined shapes is a volume wherein a second wall, intended to be in contact with the surface of the module opposite that whereon the conductive elements are distributed, is a plane wall.

18. Device according to claim 15, wherein the module stress reflow means comprise:
a plate whereon the module is positioned;
a back-plate, intended to be positioned on the plate, so as to trap and apply stress to the module in the volume with walls of predetermined shapes formed between the plate and the back-plate;
a furnace in which the plate/module/back-plate superposition is placed, and used to heat the superposition according to a suitable temperature profile to enable stress release between at least some of the constituent elements of the module.

19. Device according to claim 18, wherein the module stress reflow means also comprise:
plate/module-back-plate superposition cooling means;
means to release the module from the volume with walls of predetermined shapes.

20. Device according to claim 18, said electronic module comprising at least one substrate, wherein it comprises temperature profile application means making it possible to exceed the vitreous transition point of the substrate to modify its mechanical constants and enable it to be deformed.

21. Device according to claim 18, said electronic module comprising at least one substrate and at least one connector attached by at least one solder seam, wherein it comprises temperature profile application means making it possible to release the mechanical stress on the solder seams between said connectors and at least one organic substrate.

22. Device according to claim 18, wherein the plate comprise a housing wherein the shape is suitable to receive the module.

23. Device according to claim 18 wherein the back-plate positioning means on the plate comprise means to tighten the back-plate against the plate, making it possible to optimise the application of stress to the module in the volume with walls of predetermined shapes formed between the plate and the back-plate.

24. Production method for electronic modules of the type each comprising a set of conductive elements distributed on the bottom surface of the module, said set of conductive elements forming means to transfer the module onto a motherboard and/or electromagnetic shielding means for the bottom surface of the module and/or electrical interconnection means with the motherboard,
wherein said production method comprises a step implementing the above-mentioned method for reshaping a set of conductive elements distributed on the bottom surface of an electronic module.

25. Method according to claim 24, wherein the reshaping method implementation step is performed systematically, for all the modules manufactured.

26. Method according to claim 24, wherein the method comprises a detection step of manufactured modules, referred to as defective modules, showing a shape defect, greater than a predetermined threshold, on the tops of the free ends of the conductive elements with respect to a predetermined two-dimensional or three-dimensional envelope
and wherein the reshaping method implementation step is only performed for said defective modules.
